(19) United States
(12) Patent Application Publication
(10) Pub. No.: US 2007/0066062 A1
(43) Pub. Date: Mar. 22, 2007

(54) Landing uniformity ring for etch chamber

(75) Inventors: Te-Hsiang Liu, Hsinchu City 300 (TW); Chun-Hsiung Peng, Taoyuan City (TW)

Correspondence Address: TUNG & ASSOCIATES, Suite 120, 838 W. Long Lake Road, Bloomfield Hills, MI, 48302, US

(73) Assignee: Taiwan Semiconductor Manufacturing Co., Ltd.

(21) Appl. No.: 11/230,346

(22) Filed: Sep. 20, 2005

(51) Int. Cl. B44C 1/22; H01L 21/306; H01L 21/302

(52) U.S. Cl. 438/689; 156/915; 216/75; 156/345.51

(57) ABSTRACT

A novel landing uniformity ring for an etch chamber is disclosed. The landing uniformity ring includes an annular ring body defining a ring opening and an increased-diameter inner flange extending inwardly from the ring body, into the ring opening. When mounted in a landing uniformity ring assembly, the inner flange is disposed at a horizontal gap distance with respect to the edge of the wafer which improves the flow efficiency of exhaust gases in the etch chamber. This prevents the accumulation of polymer residues on the assembly and reduces the incidence of particle-related defects in devices being fabricated on a wafer.

### FIELD OF THE INVENTION

The present invention relates to etch chambers used to etch circuit patterns on semiconductor wafer substrates in the fabrication of integrated circuits on the substrates. More particularly, the present invention relates to a landing uniformity ring which has an enlarged inside diameter and is raised with respect to a ground ring when installed in an etch chamber to facilitate enhanced exhaust efficiency and reduce accumulation of polymer residues on the landing uniformity ring.

### BACKGROUND OF THE INVENTION

Integrated circuits are formed on a semiconductor substrate, which is typically composed of silicon. Such formation of integrated circuits involves sequentially forming or depositing multiple electrically conductive and insulative layers in or on the substrate. Etching processes may then be used to form geometric patterns in the layers or vias for electrical contact between the layers. Etching processes include “wet” etching, in which one or more chemical reagents are brought into direct contact with the substrate, and “dry” etching, such as plasma etching.

Various types of plasma etching processes are known in the art, including plasma etching, reactive ion (RI) etching and reactive ion beam etching. In each of these plasma processes, a gas is first introduced into a reaction chamber and then plasma is generated from the gas. This is accomplished by dissociation of the gas into ions, free radicals and electrons by using an RF (radio frequency) generator, which includes one or more electrodes. The electrodes are accelerated in an electric field generated by the electrodes, and the energized electrons strike gas molecules to form additional ions, free radicals and electrons, which strike additional gas molecules, and the plasma eventually becomes self-sustaining. The ions, free radicals and electrons in the plasma react chemically with the layer material on the semiconductor wafer to form residual products which leave the wafer surface and thus, etch the material from the wafer.

A conventional plasma etching system typically includes a reaction chamber having a typically grounded chamber wall. An electrode, such as a planar coil electrode, is positioned adjacent to a dielectric plate which separates the electrode from the interior of the reaction chamber. Plasma-generating source gases are provided by a gas supply (not shown). Volatile reaction products and unreacted plasma species are removed from the reaction chamber by a gas removal mechanism, such as a vacuum pump through a throttle valve.

Electrode power such as a high voltage signal is applied to the electrode to ignite and sustain a plasma in the reaction chamber. Ignition of a plasma in the reaction chamber is accomplished primarily by electrostatic coupling of the electrode with the source gases, due to the large-magnitude voltage applied to the electrode and the resulting electric fields produced in the reaction chamber. Once ignited, the plasma is sustained by electromagnetic induction effects associated with time-varying magnetic fields produced by the alternating currents applied to the electrode. The plasma may become self-sustaining in the reaction chamber due to the generation of energized electrons from the source gases and striking of the electrons with gas molecules to generate additional ions, free radicals and electrons. A semiconductor wafer is positioned in the reaction chamber and is supported by a wafer platform or ESC (electrostatic chuck). The ESC is typically electrically-biased to provide ion energies that are independent of the RF voltage applied to the electrode and that impact the wafer.

Plasma includes high-energy ions, free radicals and electrons which react chemically with the surface material of the semiconductor wafer to form reaction produces that leave the wafer surface, thereby etching a geometrical pattern or a via in a wafer layer. Plasma intensity depends on the type of etchant gas or gases used, as well as the etchant gas pressure and temperature and the radio frequency generated at the electrode. If any of these factors changes during the process, the plasma intensity may increase or decrease with respect to the plasma intensity level required for optimum etching in a particular application. Decreased plasma intensity results in decreased, and thus incomplete, etching. Increased plasma intensity, on the other hand, can cause overetching and plasma-induced damage of the wafers. Plasma-induced damage includes trapped interface charges, material defects migration into bulk materials, and contamination caused by the deposition of etch products on material surfaces. Etch damage induced by reactive plasma can alter the qualities of sensitive IC components such as Schottky diodes, the rectifying capability of which can be reduced considerably. Heavy-polymer deposition during oxide contact hole etching may cause high-contact resistance.

One type of etcher which is commonly used in the semiconductor industry to etch metal is the Lam 9600 metal etcher. The Lam Rainbow model 9600 etch system is designed for metal etching of aluminum, aluminum silicon and a limited number of other metals and metal alloys. The Lam 9600 metal etcher is a single-wafer processing tool which is designed to accommodate six-inch wafers.

The cross-sectional view of FIG. 1 illustrates structural details of the environment of an electrostatic chuck (ESC) 10 inside a Lam 9600 reaction chamber (not shown) of an Al(AlCu) metal etcher. A bottom chamber 24 is beneath the ESC 10. A typically ceramic non-landing edge ring 14 is interposed between a ground ring 12 and the outer circumference of the ESC 10. A non-landing uniformity ring 16, which is typically ceramic, is supported above the ESC 10. The non-landing uniformity ring 16 includes a base flange 18 that is supported by a ring lifter 22. An annular ring body 20 is upward-standing from the base flange 18. The non-landing uniformity ring 16 facilitates uniform metal etch rates during etching of metal on a wafer 34 supported by the ESC 10. The non-landing uniformity ring 16 is used during processes in which it is desired to etch a metal layer, such as AlCu, for example, on the wafer 34.

One of the problems frequently associated with the non-landing uniformity ring 16 is that during etching of metal layers on the wafer 34 supported on the ESC 10, polymer residues have a tendency to accumulate on the inside surface of the ring body 20. Particles of these polymer residues break off of the ring body 20 and fall on devices being fabricated on the wafer 34, leading to a high number of defects in the devices. Therefore, a landing uniformity ring 26, shown in cross-section in FIG. 2, is commonly used during etching of tungsten plugs on the wafer 34 in a tungsten plug etcher.

The cross-sectional view of FIG. 2 illustrates a landing uniformity ring 26 which is typically ceramic and is supported by the ring lifter 22, above the ESC 10. During tungsten etchback processes carried out on a wafer 34 in a tungsten plug etcher, the landing uniformity ring 26 is typically used instead of the non-landing uniformity ring 16 shown in FIG. 1. The landing uniformity ring 26 includes a base flange 28 and an annular ring body 30 which extends upwardly from the base flange 28. A beveled inner flange 32 extends inwardly from the ring body 30.

As shown in FIG. 3, the base flange 28 of the landing uniformity ring 26 typically contacts the upper surface of the ground ring 12. Furthermore, when a wafer 34 is supported on the ESC 10, a gap 36 of typically about 0.5 mm exists between the outer edge of the wafer 34 and the beveled inner flange 32 of the landing U-ring 26. As shown in FIG. 4, the inner flange 32 has an inner flange diameter 33.

One of the problems associated with the conventional landing uniformity ring 26 is that, due to the excessively narrow inner flange diameter 33 of the inner flange 32, the close proximity of the inner flange 32 with the edge of the wafer 34 interferes with the flow of exhaust gases from the etch chamber. This results in the accumulation of polymer residues on the ground ring 12. Particles from these polymer residues can potentially contaminate devices being formed on the wafer 34. Furthermore, movement of the base flange 28 with respect to the ground ring 12 generates friction which tends to form particles that may potentially contaminate devices on the wafer 34.

It has been found that reducing the inner flange diameter 33 of the beveled inner flange 32 by about 7.2 mm improves exhaust efficiency and reduces the accumulation of polymer residues on the ground ring 12. Furthermore, raising of the base flange 28 of the landing uniformity ring 26 with respect to the ground ring 12 eliminates friction between the base flange 28 and the ground ring 12, thus preventing the formation of friction-generated particles that could otherwise potentially contaminate devices being fabricated on the wafer 34.

Therefore, it is an object of the present invention to provide a new and improved landing uniformity ring for an etch chamber.

Another object of the present invention is to provide a new and improved landing uniformity ring which is suitable for enhancing the yield of devices fabricated on a wafer.

Still another object of the present invention is to provide a landing uniformity ring having a ring body defining a ring opening and an increased-diameter inner flange extending from the ring body into the ring opening.

Yet another object of the present invention is to provide a uniformity ring assembly which includes a ground ring for encircling an electrostatic chuck (ESC) and a landing uniformity ring having a base flange separated from the ground ring by a gap distance.

A still further object of the present invention is to provide a novel method for reducing defects in devices being fabricated on a wafer, which method includes providing a landing uniformity ring having a ring body and an increased-diameter inner flange extending into the ring body, supporting the landing uniformity ring over a ground ring with the landing uniformity ring positioned at a gap distance with respect to the ground ring, and supporting a wafer on an electrostatic chuck.

### SUMMARY OF THE INVENTION

In accordance with these and other objects and advantages, the present invention is generally directed to a novel landing uniformity ring for an etch chamber, particularly a LAM 9600 metal etcher. The landing uniformity ring includes a base flange, an annular ring body extending from the base flange and defining a ring opening, and an increased-diameter inner flange extending inwardly from the ring body, into the ring opening. When mounted in a landing uniformity ring assembly, the inner flange is disposed at a gap distance with respect to the edge of the wafer which improves the flow efficiency of exhaust gases in the etch chamber. This prevents the accumulation of polymer residues on the assembly and reduces the incidence of particle-related defects in devices being fabricated on a wafer.

The present invention is further directed to a uniformity ring assembly for an etch chamber. The uniformity ring assembly includes a ground ring for encircling an electrostatic chuck (ESC) and a landing uniformity ring separated from the ground ring across a gap distance. This physical contact separation of the landing uniformity ring and the ground ring prevents friction-induced particles from forming between the base flange of the landing uniformity ring and the ground ring. The landing uniformity ring typically further includes an inner flange of increased diameter to improve the flow efficiency of exhaust gases in the etch chamber.

The present invention is further directed to a novel method for reducing defects in devices being fabricated on a wafer. The method includes providing a landing uniformity ring having a ring body and an inner flange of increased diameter extending into the ring body, supporting the landing uniformity ring over a ground ring with the landing uniformity ring positioned at a gap distance with respect to the ground ring, and supporting a wafer on an electrostatic chuck with the inner flange of the landing uniformity ring disposed at a gap distance with respect to the wafer to improve the flow efficiency of exhaust gases in the etch chamber and prevent or reduce the accumulation of polymer residues on surfaces in the chamber.

### BRIEF DESCRIPTION OF THE DRAWINGS

The invention will now be described, by way of example, with reference to the accompanying drawings, in which:

FIG. 1 is a cross-section of a conventional non-landing uniformity ring assembly situated in an etcher (not shown);

FIG. 2 is a cross-section of a conventional landing uniformity ring assembly situated in an etcher;

FIG. 3 is an enlarged view of the assembly shown in FIG. 2, illustrating a small gap distance between the conventional landing uniformity ring and a wafer supported on an ESC and contact of the landing uniformity ring and a ground ring of the assembly;

FIG. 4 is a top view of the conventional landing uniformity ring, illustrating a relatively small diameter of the inner flange of the ring;

FIG. 5 is a cross-section of a landing uniformity ring assembly of the present invention;

FIG. 6 is a graph wherein baseline particle count is plotted on the Y-axis and sample number is plotted along the X-axis, illustrating a reduction in the defect count on a wafer using the landing uniformity ring assembly of the present invention as compared to using a conventional landing uniformity ring assembly; and

FIG. 7 is a top view of a landing uniformity ring of the present invention, illustrating a relatively large diameter of the inner flange of the ring as compared to the diameter of the inner flange of the conventional landing uniformity ring.

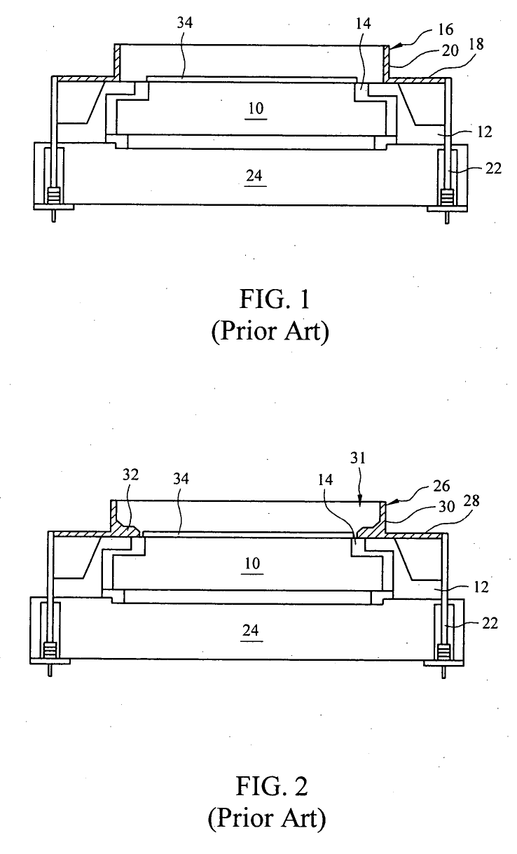

### DETAILED DESCRIPTION OF THE INVENTION

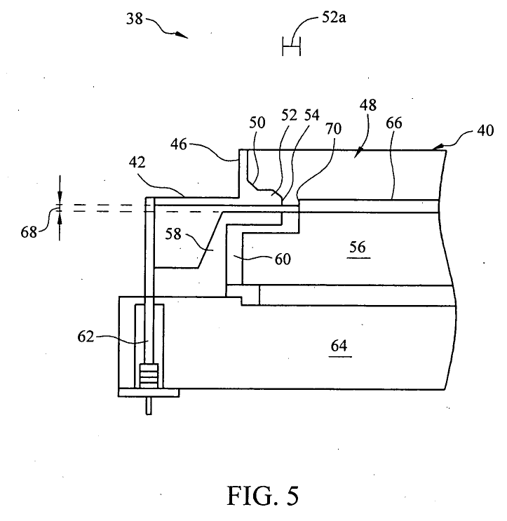

Referring to FIG. 5, an illustrative embodiment of a uniformity ring assembly according to the present invention is generally indicated by reference numeral 38. The uniformity ring assembly 38 is particularly designed for a Lam 9600 metal etch chamber (not shown) known by those skilled in the art. Such a chamber includes an electrostatic chuck (ESC) 56 for supporting a semiconductor wafer 66 during the etching of a metal layer (not shown) such as AlCu on the wafer 66. A landing edge ring 60, which is typically ceramic, encircles the ESC 56. A ground ring 58 encircles the landing edge ring 60. A bottom chamber 64 underlies the ESC 56 for the evacuation of etchant gases from the etch chamber. The uniformity ring assembly 38 further includes a landing uniformity ring 40, the structural details of which will be hereinafter further described. A ring lifter 62 engages the landing uniformity ring 40 for the raising and lowering of the landing uniformity ring 40 with respect to the ESC 56.

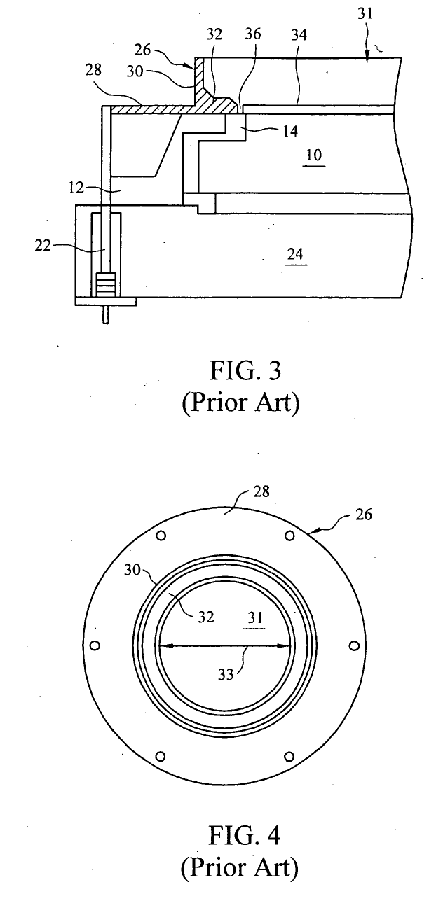

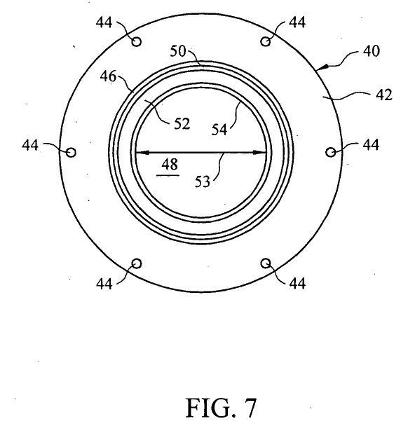

Referring to FIGS. 5 and 7, the landing uniformity ring 40 of the present invention is typically ceramic and includes an annular base flange 42 having multiple, spaced-apart openings 44 for attachment of the landing uniformity ring 40 to the ring lifter 62, typically in conventional fashion. As shown in FIG. 5, an annular ring body 46 extends generally perpendicularly from the base flange 42. The ring body 46 defines a central ring opening 48. A beveled ring shoulder 50 typically extends around the interior surface of the ring body 46. An annular inner flange 52, typically having a flange bevel 54, extends from the ring shoulder 50, into the ring opening 48. As shown in FIG. 7, the inner flange 52 preferably has an inner flange diameter 53 which equals the diameter of the ring opening 48. Accordingly, the diameter of the ring opening 48 of the landing uniformity ring 40 according to the present invention is preferably about 14.4 mm greater than the diameter of the ring opening 31 (FIG. 4) of the conventional landing uniformity ring 26. As shown in FIG. 5, this corresponds to a length reduction 52a of typically about 7.2 mm at each point along the inner flange 52. Accordingly, as shown in FIG. 5, when the wafer 66 is supported on the ESC 56 during a metal etch process, the edge of the wafer 66 is separated from the inner flange 52 by a horizontal gap distance 70 of typically about 7.7 mm (as compared to a gap distance 36 of typically about 0.5 mm in the case of the conventional landing uniformity ring 26, as shown in FIG. 3). This improves exhaust efficiency and prevents or substantially reduces accumulation of polymer residues (not shown) on the ground ring 58 during the etch process. The landing uniformity ring 40 has a height of up to typically about 50 mm, and the width of the ring body 46 of the landing uniformity ring 40 from the outer surface of the ring body 46 to the flange bevel 54 is up to typically about 24 mm.

As further shown in FIG. 5, in the uniformity ring assembly 38, the base flange 42 of the landing uniformity ring 40 is preferably positioned at a vertical gap distance 68 with respect to the ground ring 58. This may be accomplished by adjusting the height of the ring lifter 62, according to the knowledge of those skilled in the art. Preferably, the vertical gap distance 68 is about 3.0 mm. Accordingly, during an etch process carried out in the etch chamber, the base flange 42 is incapable of rubbing against the ground ring 58 and generating particles which could otherwise contaminate device features being fabricated on the wafer 66.

In typical application of the invention, the landing uniformity ring 40 is installed in a Lam 9600 etch chamber (not shown) as a component of the uniformity ring assembly 38, in the manner heretofore described with respect to FIG. 5. Accordingly, the vertical gap distance 68 exists between the base flange 42 and the upper surface of the ground ring 58. A semiconductor wafer 66, on which is provided a metal layer (not shown) such as AlCu, is placed on the electrostatic chuck 56 for etching of the metal layer. The horizontal gap distance 70 of typically about 7.7 mm exists between the edge of the wafer 66 and the inner flange 52. During the etch process, the increased width of the horizontal gap distance 70, as compared to that obtained using the conventional landing uniformity ring, improves exhaust efficiency and prevents or substantially reduces accumulation of polymer residues (not shown) on the ground ring 58 during the etch process. Furthermore, due to the vertical gap distance 68 between the base flange 42 and the upper surface of the ground ring 58, the base flange 42 is incapable of rubbing against the ground ring 58 and generating particles which could otherwise contaminate device features being fabricated on the wafer 66, as heretofore noted.

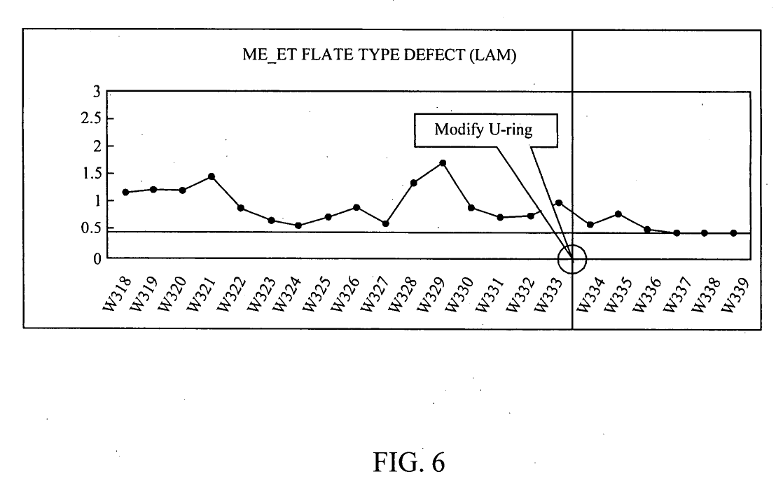

Referring next to the graph of FIG. 6, wherein baseline defect count is plotted on the Y-axis and successive etch samples are plotted by number along the X-axis. It will be appreciated by those skilled in the art that the present invention substantially reduces the quantity of potential circuit-contaminating contaminating particles generated during an etch process, thereby reducing the number of defects formed in devices fabricated on a wafer. The defect counts of samples resulting from use of the conventional landing uniformity ring are plotted to the left side of the vertical line in the graph, whereas the defect counts of samples resulting from use of the landing uniformity ring of the present invention are plotted to the right side of the vertical line. Accordingly, the baseline defect count was reduced from levels as high as 2 (using the conventional landing uniformity ring) to a level of about 0.5 using the landing uniformity ring of the present invention.

While the preferred embodiments of the invention have been described above, it will be recognized and understood that various modifications can be made in the invention and the appended claims are intended to cover all such modifications which may fall within the spirit and scope of the invention.

What is claimed is:

1. A landing uniformity ring for an etch chamber, comprising:
an annular ring body defining a ring opening, said ring body having a width of no greater than about 24 mm; and
an inner flange extending into said ring opening.

2. The landing uniformity ring of claim 1 wherein said ring body and said inner flange are ceramic.

3. The landing uniformity ring of claim 1 wherein said ring body having a height of not greater than about 50 mm.

4. The landing uniformity ring of claim 1 further comprising a ring shoulder between said ring body and said inner flange.

5. The landing uniformity ring of claim 1 wherein said inner flange is beveled.

6. The landing uniformity ring of claim 1 further comprising an annular base flange extending outwardly from said ring body.

7. The landing uniformity ring of claim 6 wherein said ring body is disposed in substantially perpendicular relationship to said base flange.

8. The landing uniformity ring of claim 6 further comprising a plurality of openings extending through said base flange.

9. The landing uniformity ring of claim 6 wherein said ring body, said inner flange and said base flange are ceramic.

10. A uniformity ring assembly for an etch chamber having an electrostatic chuck for supporting a wafer, comprising:
a ground ring for encircling the electrostatic chuck; and
a landing uniformity ring positioned at a vertical gap distance with respect to said ground ring.

11. The uniformity ring assembly of claim 10 wherein said vertical gap distance is about 3 mm.

12. The uniformity ring assembly of claim 10 wherein said landing uniformity ring is ceramic.

13. The uniformity ring assembly of claim 10 wherein said landing uniformity ring comprises an annular ring body defining a ring opening and an inner flange extending into said ring opening.

14. The uniformity ring assembly of claim 13 further comprising a ring shoulder between said ring body and said inner flange.

15. The uniformity ring assembly of claim 13 wherein said inner flange is beveled.

16. The uniformity ring assembly of claim 13 further comprising an annular base flange extending outwardly from said ring body.

17. The uniformity ring assembly of claim 16 further comprising a plurality of openings extending through said base flange.

18. A method of reducing defects in devices fabricated on a wafer during etching of a metal layer on the wafer in an etch chamber having an electrostatic chuck and a ground ring encircling said electrostatic chuck, comprising:
providing a landing uniformity ring having an annular ring body defining a ring opening and an inner flange extending into said ring opening;
positioning said landing uniformity ring at a vertical gap distance with respect to said ground ring;
supporting said wafer on said electrostatic chuck; and
etching said metal layer.

19. The method of claim 18 wherein said vertical gap distance is about 3 mm.

20. The method of claim 18 wherein said wafer is disposed at a horizontal gap distance of about 7.7 mm with respect to said inner flange.

21. The method of claim 18 further comprising an annular base flange extending outwardly from said ring body and wherein said base flange is positioned at said vertical gap distance with respect to said ground ring.
